(19) United States
(12) Patent Application Publication
(10) Pub. No.: US 2026/0343840 A1
(43) Pub. Date: Oct. 29, 2026

(54) MAGNETIC SHIELDING STRUCTURE, MAGNETIC ATTRACTION POSITIONING STRUCTURE, AND WIRELESS CHARGING DEVICE

(71) Applicant: Lanto Electronic Limited, Kunshan City (CN)

(72) Inventor: Liefeng JIN, Kunshan (CN)

(73) Assignee: Lanto Electronic Limited, Kunshan City (CN)

(21) Appl. No.: 19/310,586

(22) Filed: Aug. 26, 2025

(30) Foreign Application Priority Data
Apr. 27, 2025 (CN) 202520813279.9
Apr. 27, 2025 (CN) 202520813987.2

(51) Int. Cl. H05K 9/00; H01F 7/02; H02J 50/10; H02J 50/70

(52) U.S. Cl. CPC H05K 9/0075; H01F 7/0215; H02J 50/10; H02J 50/70

(57) ABSTRACT

A magnetic shielding structure includes a magnetic material layer, and a first edge-wrapping structure layer and a second edge-wrapping structure layer that are provided on both sides of the magnetic material layer, respectively. The magnetic material layer includes a first covering layer, an intermediate layer, and a second covering layer that are sequentially stacked, an area of the intermediate layer is less than an area of each of the first covering layer and the second covering layer, and the first covering layer and the second covering layer wrap the intermediate layer from both sides of the intermediate layer, respectively.

### CROSS-REFERENCE TO RELATED APPLICATIONS

This application claims priority to Chinese Patent Application No. 202520813987.2, filed on Apr. 27, 2025, and Chinese Patent Application No. 202520813279.9, filed on Apr. 27, 2025. The contents of the above identified applications are hereby incorporated herein by reference in their entireties.

### TECHNICAL FIELD

The present disclosure relates to the technical field of wireless charging, and in particular to a magnetic shielding structure, a magnetic attraction positioning structure, and a wireless charging device.

### BACKGROUND

Wireless charging technology refers to the use of electromagnetic wave induction for charging. The wireless charging technology is based on the theory of wireless power transmission and has ushered in rapid development with the popularization of consumer electronic products. Currently, the mainstream wireless charging technologies can be divided into three types: electromagnetic induction (Qi standard), magnetic resonance (A4WP standard) and radio frequency. The Qi standard based on the principle of electromagnetic induction has been widely used due to its technical maturity and cost advantages. Wireless charging devices generate alternating electric fields when working, and the magnetic shielding materials in the wireless charging device can reduce magnetic field leakage, improve energy transmission efficiency, and prevent electromagnetic interference (EMI) from affecting surrounding electronic devices. Common magnetic shielding materials mainly include soft magnetic alloys, ferrites, amorphous or nanocrystalline alloys, and composite shielding materials.

An electromagnetic induction wireless charging device includes a magnetic shielding material layer and an electromagnetic coil provided on the magnetic shielding material. The magnetic shielding material layer is generally formed by processing a plurality of layers of nanocrystals.

### SUMMARY

According to various embodiments, the present disclosure provides a magnetic shielding structure, a magnetic attraction positioning structure, and a wireless charging device.

A magnetic shielding structure is provided, which includes:
a magnetic material layer;
a first edge-wrapping structure layer and a second edge-wrapping structure layer are provided on both sides of the magnetic material layer, respectively;
wherein the magnetic material layer includes a first covering layer, an intermediate layer, and a second covering layer that are sequentially stacked, an area of the intermediate layer is less than an area of each of the first covering layer and the second covering layer, and the first covering layer and the second covering layer wrap the intermediate layer from both sides of the intermediate layer, respectively.

In an embodiment, the edge-wrapping structure layer includes an insulating edge-wrapping structure.

In an embodiment, at least one of the first covering layer, the intermediate layer, and the second covering layer includes a plurality of magnetic material sheets.

In an embodiment, the magnetic material sheet is made of a magnetic material, and the magnetic material is at least one selected from the group consisting of a ferrite material, an amorphous alloy, a nanocrystalline alloy, a soft magnetic composite material, and a flexible magnetic film.

In an embodiment, the intermediate layer is provided with a first avoidance opening.

In an embodiment, the magnetic shielding structure further includes a shielding layer provided on a side of the first edge-wrapping structure layer or the second edge-wrapping structure layer away from the magnetic material layer.

In an embodiment, the shielding layer is a sheet structure made of a metal material.

In an embodiment, the metal material is copper.

In an embodiment, the magnetic shielding structure further includes adhesive layers provided between the first edge-wrapping structure layer, the magnetic material layer, and the second edge-wrapping structure layer.

In an embodiment, the magnetic shielding structure further includes adhesive layers provided between the first covering layer, the intermediate layer, and the second covering layer.

A magnetic attraction positioning structure is provided, which includes the magnetic shielding structure as described above and a positioning magnetic ring stacked on the magnetic shielding structure in a stacking direction, wherein the magnetic shielding structure covers the positioning magnetic ring in the stacking direction.

In an embodiment, an edge of the magnetic shielding structure is aligned with an edge of the positioning magnetic ring.

In an embodiment, an edge of the magnetic shielding structure extends beyond an edge of the positioning magnetic ring in a radial direction of the positioning magnetic ring.

In an embodiment, an edge of the magnetic shielding structure extends beyond an edge of the positioning magnetic ring in an axial direction of the positioning magnetic ring.

In an embodiment, the edge of the magnetic shielding structure is provided with a stepped structure.

In an embodiment, the edge of the magnetic shielding structure is folded inward towards the positioning magnetic ring to form a curled edge.

A magnetic attraction positioning structure is further provided, which includes the magnetic shielding structure as described above and a positioning magnetic ring surrounding the positioning magnetic ring.

In an embodiment, the positioning magnetic ring has a notch, and the magnetic shielding structure has a protrusion extending into the notch.

In an embodiment, the protrusion is adapted to the notch.

In an embodiment, the positioning magnetic ring includes a plurality of magnets distributed in a ring array.

In an embodiment, the positioning magnetic ring is provided with a second avoidance opening.

A wireless charging device is further provided, which includes the magnetic attraction positioning structure as described above and an electromagnetic coil, the magnetic shielding structure of the magnetic attraction positioning structure covers the electromagnetic coil, and the electromagnetic coil is surrounded by the positioning magnetic ring of the magnetic attraction positioning structure.

### BRIEF DESCRIPTION OF THE DRAWINGS

In order to illustrate the technical solutions in the embodiments of the present disclosure or the conventional technology more clearly, the following will briefly describe the accompanying drawings that will be used in the description of the embodiments or the traditional technology. It is clear that the accompanying drawings in the following description are only some embodiments of the present disclosure. For those skilled in the art, other drawings can also be obtained based on these drawings without creative effort.

FIG. 1 is a schematic diagram of a magnetic shielding structure in the related art.

FIG. 2 is a schematic diagram of a magnetic shielding stack structure in the related art.

FIG. 3 is a schematic diagram of a magnetic shielding structure according to an embodiment.

FIG. 4 is a schematic diagram of a magnetic shielding stack structure according to an embodiment.

FIG. 5 is an exploded view of a magnetic shielding structure according to an embodiment.

FIG. 6 is a schematic diagram illustrating an edge of a magnetic shielding structure aligned with a positioning magnetic ring according to an embodiment.

FIG. 7 is a schematic diagram illustrating an edge of the magnetic shielding structure extending beyond a positioning magnetic ring.

FIG. 8 is a schematic diagram illustrating a distribution of magnetic induction lines of a magnetic attraction positioning structure in the related art.

FIG. 9 is a schematic diagram illustrating a distribution of magnetic induction lines of a magnetic attraction positioning structure according to an embodiment.

FIG. 10 is a schematic diagram of a wireless charging device according to an embodiment.

FIG. 11 is a schematic diagram of a wireless charging device according to another embodiment.

FIG. 12 is a schematic diagram of a wireless charging device according to yet another embodiment.

FIG. 13 is a schematic diagram of a wireless charging device according to yet another embodiment.

FIG. 14 is a schematic structural diagram of a wireless charging device according to an embodiment.

Description of the reference numerals: 10, magnetic shielding structure; 100, first edge-wrapping structure layer; 140, protrusion; 200, magnetic material layer; 210, first covering layer; 220, intermediate layer; 230, second covering layer; 240, first avoidance opening; 300, second edge-wrapping structure layer; 400, shielding layer; 500, electromagnetic coil; 600, positioning magnetic ring; 610, notch; 620, magnet; 630, second avoidance opening.

### DETAILED DESCRIPTION OF THE EMBODIMENTS

In order to facilitate the understanding of the present disclosure, the present disclosure will be described more fully below with reference to relevant attached drawings. Preferred embodiments of the present disclosure are illustrated in the drawings. However, the present disclosure can be implemented in many different forms and is not limited to the embodiments described herein. On the contrary, providing these embodiments is to assist understanding the content disclosed by the present disclosure more fully and thoroughly.

Unless otherwise defined, all technical and scientific terms used herein have the same meaning as commonly understood by those skilled in the technical field of the present disclosure. The terms used in the specification of the present disclosure herein are only for the purpose of describing specific embodiments, and are not intended to limit the present disclosure.

It should be understood that the terms “first”, “second”, etc. used in the present disclosure can be used herein to describe various elements, but these elements are not limited by these terms. These terms are only used to distinguish a first element from another element. For example, a first resistor could be referred to as a second resistor, and, similarly, a second resistor could be referred to as a first resistor without departing from the scope of the present disclosure. The first resistor and the second resistor are both resistors, but they are not the same resistor.

It can be understood that if the connected circuits, modules, units, etc. have electrical signals or data transmission between each other, the “connection” in the following embodiments should be understood as “electrical connection”, “communication connection”, etc.

It will be understood that “at least one” means one or more, and “plurality” means two or more. “At least a portion of an element” means a part or the whole of an element.

As used herein, the singular forms “a”, “an” and “the” may include the plural forms as well, unless the context clearly indicates otherwise. It should also be understood that the terms “include/comprises” or “have” and the like specify the presence of stated features, wholes, steps, operations, components, parts or combinations thereof, but do not exclude the possibility of the presence or addition of one or more other features, wholes, steps, operations, components, parts or combinations thereof. Meanwhile, the term “and/or” used in this specification includes any and all combinations of the relevant listed items.

In the related art, the thickness of each layer of nanocrystal of a magnetic shielding material layer is 10 μm to 25 μm, and the hardness of nanocrystalline materials is generally in a range of 500~1500HV, which is much higher than that of traditional ferrite and amorphous materials due to its ultrafine grain structure and the strengthening effect of alloy elements, which also makes it brittle and prone to chipping or edge collapse during processing. Currently, in order to improve this situation, films (such as PET, PI and other polymer materials) are usually used for edge wrapping. The edge wrapping not only provides additional mechanical protection to prevent further damage to the nanocrystal material during production and assembly, but also effectively suppresses the potential risk caused by nanocrystal breakage.

When the thickness of the magnetic shielding material layer exceeds 25 μm, the nanocrystalline metallographic structure will become uneven and the performance will decrease sharply. Therefore, in order to achieve better performance, multiple layers of nanocrystals are currently combined into one. The multi-layer nanocrystal structure can improve the magnetic permeability of the material, especially making it more stable at high frequencies. This thin layer structure improves the magnetic saturation characteristics of the magnetic material under high frequency conditions while maintaining high performance. In order to achieve better performance of the magnetic material layer, different regions of the magnetic material layer have different thicknesses. In order to achieve different thicknesses, different numbers of nanocrystal layers are provided in different regions of the magnetic material layer.

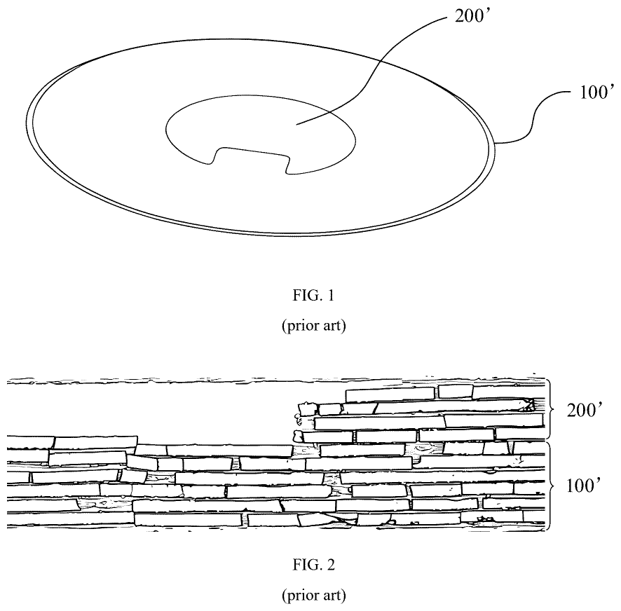

The center of the electromagnetic coil in the wireless charging device is the area with the strongest magnetic field, and is also the area most likely to be saturated. When the magnetic field strength increases, the magnetic material may reach a state of magnetic saturation, thereby reducing its magnetic permeability and causing a decrease in efficiency. In order to raise the magnetic field to a higher level, and ensure that the magnetic material does not form magnetic saturation and the thickness of the product is minimized, the solution is to thicken the magnetic material layer corresponding to the center area of the electromagnetic coil, that is, as shown in FIG. 1, to cover the magnetic material layer 100′ with a small area of magnetic material layer 200′. However, there is a step between the magnetic material layer 200′ with a less area and the magnetic material layer 100′ with a larger area, and there are obvious burrs at the step, as shown in FIG. 2. Due to high hardness and sharp edges, burrs can easily pierce various protective films in the device, especially in high temperature or vibration environments, and are more likely to fall off or deform, resulting in greater safety hazards, including short circuit and even battery explosion. Moreover, when the wireless charging device is in operation, the coil is in a high temperature state for a long time, and the aging of the adhesive layer and insulation layer on the coil wire is accelerated. As the use time of the coil increases, the number of pinholes in the coil gradually increases. The pinholes may form micro short circuits with the nanocrystals, which further reduces the charging efficiency.

In order to minimize the risk of burrs and debris during the processing and use of nanocrystalline materials, a design solution that can improve product quality, prolong service life and further enhance product safety is needed.

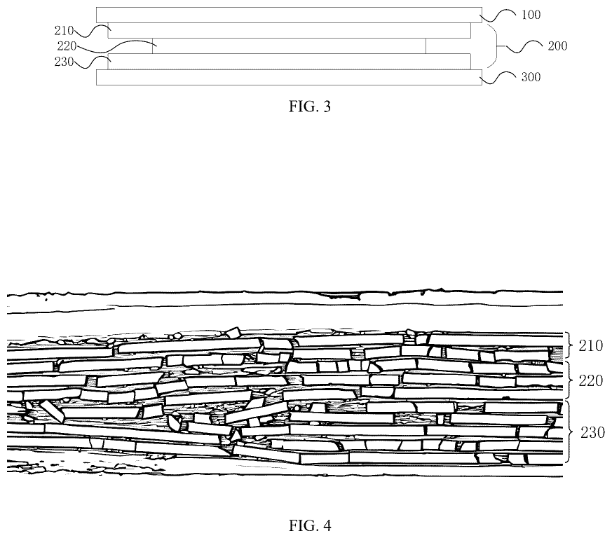

A magnetic shielding structure 10 is provided according to an embodiment of the present disclosure. As shown in FIG. 3, the magnetic shielding structure 10 is of a three-layers structure, which includes a first edge-wrapping structure layer 100, a magnetic material layer 200, and a second edge-wrapping structure layer 300 that are sequentially arranged.

The first edge-wrapping structure layer 100 and the second edge-wrapping structure layer 300 are respectively provided on upper and lower sides of the magnetic material layer 200. The first edge-wrapping structure layer 100 and the second edge-wrapping structure layer 300 are configured to enhance the mechanical strength of the magnetic material layer 200 and reduce edge magnetic leakage, so that the magnetic path can be constrained within the magnetic shielding structure 10. In addition, the first edge-wrapping structure layer 100 and the second edge-wrapping structure layer 300 can provide insulation protection for an internal structure of the magnetic shielding structure 10.

Exemplarily, the specific shapes and materials of the first edge-wrapping structure layer 100 and the second edge-wrapping structure layer 300 are adapted to actual application requirements. The specific shapes and materials of the first edge-wrapping structure layer 100 and the second edge-wrapping structure layer 300 are independent of each other, and they can be made of the same material or different types of materials. Exemplarily, the first edge structure layer 100 and the second edge structure layer 300 have high mechanical strength and can assist in suppressing magnetic leakage. Therefore, the preparation materials of the first edge structure layer 100 and the second edge structure layer 300 can be selected from the following types, including: a thermoplastic polymer, for example, which is a polymer with, such as PPS (polyphenylene sulfide), PA6T (high temperature resistant nylon), LCP (liquid crystal polymer), etc. as a base material, and glass fiber for enhancing stiffness, magnetic powder, such as FeSiAl, for enhancing edge shielding as a filler; epoxy resin molded edge wrapping, for example, which is a polymer with epoxy resin and curing agent (such as bisphenol A) as a base material and Al₂O₃ powder for thermal conductivity and carbon fiber for conductivity and suppression of edge eddy currents as modifiers; magnetic polymer composites, for example, which adopts TPU (thermoplastic polyurethane) as a base material and flaky carbonyl iron powder as a functional filler; UV-cured acrylate edge wrapping, for example, which is a polymer with acrylate resin and nano-SiO₂ for enhancing wear resistance as UV adhesive and a carbon nanotube having a weight percentage of 0.5 wt % for conducting static electricity as an additive. Other embodiments are similar to the above, and can be selected by technicians according to actual application scenarios, and are not described in detail here.

The magnetic material layer 200 includes a first covering layer 210, an intermediate layer 220, and a second covering layer 230 that are sequentially stacked. An area of the intermediate layer 220 is less than an area of each of the first covering layer 210 and the second covering layer 230, and the first covering layer 210 and the second covering layer 230 respectively wrap the intermediate layer 220 from both sides of the intermediate layer 220 to form a sandwich-like stacked structure.

Specifically, the first covering layer 210, the intermediate layer 220, and the second covering layer 230 may include a single magnetic material sheet, or may be composited from a plurality of magnetic material sheets, and the plurality of magnetic material sheets of the first covering layer 210, the intermediate layer 220, and the second covering layer 230 are independent from each other. In practice, the number of layers of the magnetic material sheets in the first covering layer 210, the intermediate layer 220, and the second covering layer 230 can be determined by technicians according to application requirements, such as product thickness, magnetic shielding performance, etc.

Exemplarily, as shown in FIG. 4, the magnetic material sheet may be a nanocrystalline sheet made of a nanocrystalline alloy material. Correspondingly, the first covering layer 210, the intermediate layer 220, and the second covering layer 230 are compounded with a plurality of layers of magnetic material sheets. For example, the first covering layer 210 is compounded with two layers of nanocrystalline sheets, the intermediate layer 220 is compounded with three layers of nanocrystalline sheets, and the second covering layer 230 is compounded with five layers of nanocrystalline sheets. In this way, the first covering layer 210, the intermediate layer 220 and the second covering layer 230 can be obtained by compounding a plurality of layers of magnetic material sheets, which helps to adjust the layered structure of the first covering layer 210, the intermediate layer 220, and the second covering layer 230 according to actual usage requirements and improves the flexibility of structural design.

Specifically, the magnetic material sheet can be made of a magnetic material, and the magnetic material can include a ferrite material, an amorphous alloy, a nanocrystalline alloy, a soft magnetic composite material, and a flexible magnetic film, etc. Specifically, the magnetic material sheet can be made of a single magnetic material or a combination of a plurality of magnetic materials, so that the magnetic material sheet can meet the requirements of different application scenarios, such as magnetic shielding performance requirements, mechanical strength requirements, corrosion resistance and heat resistance, etc. The specific material can be determined by technicians according to actual usage requirements and will not be described in detail.

In an embodiment, in the preparation process of the first covering layer 210, the intermediate layer 220, and the second covering layer 230 by compounding magnetic material sheets, the composite treatment between the magnetic material sheets can be selected according to application requirements, such as lamination bonding composite, magnetic thin film deposition composite, woven fiber composite, powder sintering composite and gradient material composite and other sheet material composite processing processes. Furthermore, the composite treatment process described above can be determined by technicians according to application requirements, and may be one of them, such as lamination bonding, or may be a combination of multiple processes, such as lamination bonding and gradient composite.

Specifically, the first covering layer 210, the intermediate layer 220, and the second covering layer 230 in this embodiment are all planar sheet structures, and the first covering layer 210, the intermediate layer 220, and the second covering layer 230 are stacked in a direction perpendicular to their own planes. In this embodiment, a horizontal plane is taken as an example to describe a reference plane parallel to the first covering layer 210, the intermediate layer 220, and the second covering layer 230. In this embodiment, the area of the intermediate layer 220 is less than the area of the first covering layer 210 and the second covering layer 230, which means that a projected area of the intermediate layer 220 on the horizontal plane is less than a projected area of each of the first covering layer 210 and the second covering layer 230 on the horizontal plane. The first covering layer 210 and the second covering layer 230 wrap both sides of the intermediate layer 220, which means that a projection of the intermediate layer 220 on the horizontal plane is covered by a projection of each of the first covering layer 210 and the second covering layer 230 on the horizontal plane. That is, from the top view and the bottom view of the horizontal plane, the intermediate layer 220 is completely covered and shielded by the first covering layer 210 and the second covering layer 230, respectively. In the subsequent lamination and bonding process, portions of the first covering layer 210 and the second covering layer 230 that exceed the intermediate layer 220 are filled into the intermediate layer 220, and finally the first covering layer 210 and the second covering layer 230 wrap the intermediate layer 220.

The magnetic shielding structure 10 includes the first edge-wrapping structure layer 100, the magnetic material layer 200, and the second edge-wrapping structure layer 300. The first edge-wrapping structure layer 100 and the second edge-wrapping structure layer 300 are respectively provided on both sides of the magnetic material layer 200 for protecting the magnetic material layer 200 and providing mechanical support and insulation protection. The magnetic material layer 200 is configured to provide a low magnetic resistance path and reduce electromagnetic interference. The magnetic material layer 200 includes the first covering layer 210, the intermediate layer 220, and the second covering layer 230 that are stacked in sequence. The area of the intermediate layer 220 is less than the area of the first covering layer 210 and the area of the second covering layer 230, and the first covering layer 210 and the second covering layer 230 respectively wrap the intermediate layer 220 from both sides of the intermediate layer 220, thereby forming a plurality of magnetic core layers. The magnetic core layers refer to the first covering layer 210, the intermediate layer 220 and the second covering layer 230, that is, the magnetic material layer 200 includes a plurality of magnetic core layers, and the plurality of magnetic core layers are stacked to form a stack structure. An area of the magnetic core layer located in the middle of the stack structure of the magnetic material layer 200 is less than an area of each of the magnetic core layers located on both sides of the stack structure. The magnetic core layers located on both sides of the stack structure wrap the magnetic core layers in the middle of the stack structure. In practice, since the plurality of magnetic core layers provided in the magnetic material layer 200 are stacked, the magnetic core layer located in the middle of the stack structure has a small area, the magnetic core layers located on both sides of the stack structure have a large area, and the magnetic core layers located on both sides of the stack structure wrap the magnetic core layer having a small area in the middle of the stack structure, so that a stepped wrapping structure symmetrically distributed on both sides of the magnetic material layer 200 is realized, which helps to limit a position where a step difference exists to a middle region of the magnetic material layer 200, and evenly distribute the step difference size to both sides of the stack structure, thereby reducing the step difference size caused by the area difference. On the other hand, stepped stacking helps to disperse mechanical stress, thereby avoiding sharp-angle contact between layers and eliminating edge burrs and interlayer microcracks caused by abrupt changes in area of traditional tacking. In applications, the magnetic core layer having a small area in the middle of the stack structure helps to reduce the concentration of high-frequency eddy currents, and the magnetic core layer having a large area on both sides of the stack structure helps to reduce the eddy current losses in the application.

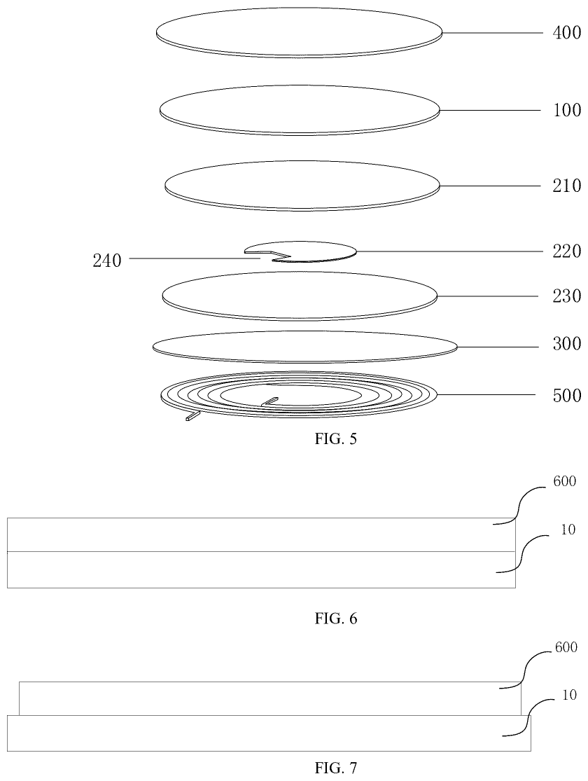

Referring to FIG. 5, when in use, the magnetic shielding structure 10 is provided inside a wireless charging device, the structure and shape of the magnetic shielding structure 10 are limited by the structure of the wireless charging device, and the magnetic shielding structure 10 needs to work together with related devices such as an electromagnetic coil 500, and a connector or a coil of the related devices such as the electromagnetic coil 500 may need to be embedded in the magnetic shielding structure 10. In such scenarios, it is difficult for the magnetic shielding structure 10 to maintain a regular shape such as a circle, a rectangle, etc. In view of the above problems, in the magnetic shielding structure of the embodiment, the intermediate layer 220 is provided with a first avoidance opening 240. In this way, a flexible and controllable space can be formed in the magnetic shielding structure 10 through the first avoidance opening 240, so that the magnetic shielding structure 10 can satisfy the purpose of avoiding other assembly structures or further reducing the thickness of the magnetic material layer 200.

Specifically, the first avoidance opening 240 may be located at an edge of the intermediate layer 220, that is, a groove-shaped notch is formed at the edge of the intermediate layer 220, so as to avoid an assembly structure such as a coil interface. The shape of the first avoidance opening 240 can be rectangular, circular, triangular, etc., which can be determined by technicians according to application requirements. In another embodiment, the first avoidance opening 240 may alternatively be located in the middle of the intermediate layer 220, that is, a through hole that meets the notch application requirements is formed in the middle of the intermediate layer 220, so as to meet the requirement of forming a space in the middle of the magnetic shielding structure 10. In the above two embodiments of the first avoidance opening 240, since the first avoidance opening 240 is provided in the intermediate layer 220, new edge burrs may be formed in the magnetic shielding structure 10, resulting in structural instability. Therefore, rounding treatment can be performed at the first avoidance opening 240 of the intermediate layer 220. Exemplarily, the rounding treatment may refer to treating a corner of the first avoidance opening 240 to convert a sharp angle structure into a rounded corner, or may refer to adding a chamfer structure to an included angle of the section of the first avoidance opening 240 to convert the corner at the included angle from a sharp corner into a rounded corner. In this way, even if a plurality of first avoidance openings 240 of various shapes are added, the effect of reducing edge burrs in the magnetic material layer 200 can be maintained.

In one embodiment, as shown in FIG. 5, the magnetic shielding structure 10 may further include a shielding layer 400. Specifically, the shielding layer 400 is provided on a side of the first edge-wrapping structure layer 100 or the second edge-wrapping structure layer 300 away from the magnetic material layer 200. In practice, the shielding layer 400 can suppress magnetic field leakage through eddy current loss, thereby improving the shielding performance and application stability of the magnetic shielding structure 10.

Exemplarily, the shielding layer 400 has the characteristics of high thermal conductivity and electrical conductivity or magnetic conductivity. The shielding layer 400 may be a sheet structure made of a metal material, such as a copper foil. The shielding layer 400 may alternatively be a metal-based composite material, a flexible thermally conductive insulating material, a magnetic thermal conductive composite layer, a phase change material combined with a metal layer, etc.

In an embodiment, the magnetic shielding structure 10 further includes adhesive layers provided between the first edge-wrapping structure layer 100, the magnetic material layer 200, and the second edge-wrapping structure layer 300, and the magnetic shielding structure 10 further includes adhesive layers provided between the first covering layer 210, the intermediate layer 220, and the second covering layer 230 of the magnetic material layer 200. In this way, the functional layers on both sides of the adhesive layer can be strengthened through the adhesive layer, thereby improving the stability of the magnetic shielding structure 10 and the stability of the electromagnetic performance.

Exemplarily, the adhesive layer can be an insulating adhesive layer, such as an epoxy resin adhesive, a polyimide adhesive film, and a silicone rubber. The adhesive layer can also be a thermally conductive adhesive layer, such as a conductive adhesive containing metal particles, a graphene-filled adhesive, and a ceramic-filled adhesive, etc. The adhesive layer can also be a magnetically conductive adhesive layer, such as a magnetic particle adhesive and a nanocrystalline alloy adhesive, etc. The adhesive layer can also be a multifunctional composite adhesive layer, such as a gradient adhesive layer, a phase change material adhesive layer, etc. The adhesive layer may be directly attached and fixed between the layer structures, or may be fixed between the layer structures through a process such as hot pressing and curing.

Referring to FIG. 5, the magnetic shielding structure 10 is a stacked layer structure, which includes the shielding layer 400, the first edge-wrapping structure layer 100, the first covering layer 210, the intermediate layer 220, the second covering layer 230, and the second edge-wrapping structure layer 300 that are arranged from top to bottom. When in use, the magnetic shielding structure 10 covers the electromagnetic coil 500. Specifically, the shielding layer 400 is a copper foil sheet. The first edge-wrapping structure layer 100 is made of polymer and has a sheet-like structure. The first covering layer 210 is a nanocrystalline layer including two layers of nanocrystalline material sheets and is circular. The intermediate layer 220 is a nanocrystalline layer including three layers of nanocrystalline material sheets and is circular. The edge of the intermediate layer 220 is provided with a rectangular notch. The position of the rectangular notch corresponds to a connector of the electromagnetic coil 500, so that the overall thickness of the product is thin. The second covering layer 230 is a nanocrystalline layer including five layers of nanocrystalline material sheets and is circular. The second edge-wrapping structure layer 300 is made of polymer and has a sheet-like structure.

In this way, the first covering layer 210 and the second covering layer 230 wrap the intermediate layer 220 from both sides thereof, thereby improving the stability of the magnetic shielding structure 10.

Referring to FIG. 6, an embodiment of the present disclosure also provides a magnetic attraction positioning structure, which includes the magnetic shielding structure 10 as described in any one of the above embodiments and a positioning magnetic ring 600. The magnetic shielding structure 10 is configured to constrain a magnetic field path, suppress magnetic field diffusion and reduce electromagnetic interference. The positioning magnetic ring 600 is configured to attract a magnetic ring of a corresponding device and provide magnetic attraction force to achieve the positioning and attraction function.

In an embodiment, the magnetic shielding structure 10 and the positioning magnetic ring 600 are stacked in a stacking direction, and the magnetic shielding structure 10 covers the positioning magnetic ring 600 in the stacking direction. Specifically, the magnetic shielding structure 10 covering the positioning magnetic ring 600 in the stacking direction may include two situations, where an edge of the magnetic shielding structure 10 is aligned with an edge of the positioning magnetic ring 600, and an edge of the magnetic shielding structure 10 extends beyond an edge of the positioning magnetic ring 600.

Referring to FIG. 6, in the illustrated embodiment, the edge of the magnetic shielding structure 10 is aligned with the edge of the positioning magnetic ring 600. Specifically, the magnetic shielding structure 10 and the positioning magnetic ring 600 in this embodiment are both planar sheet structures, and the magnetic shielding structure 10 and the positioning magnetic ring 600 are stacked in a direction perpendicular to the magnetic shielding structure 10 and the positioning magnetic ring 600. In this embodiment, a horizontal plane can be taken as an example of a reference plane parallel to the magnetic shielding structure 10 and the positioning magnetic ring 600 for explanation. Thus, the magnetic shielding structure 10 in this embodiment covers the positioning magnetic ring 600 in the stacking direction. For a specific example, the magnetic shielding structure 10 and the positioning magnetic ring 600 are respectively placed on two horizontal planes parallel to each other, and the magnetic shielding structure 10 and the positioning magnetic ring 600 are stacked along a vertical axis. At this time, the stacking direction of the magnetic shielding structure 10 and the positioning magnetic ring 600 is a vertical direction. Specifically, the magnetic shielding structure 10 in this embodiment covers the positioning magnetic ring 600 in the stacking direction, which means that a projection of the magnetic shielding structure 10 on the horizontal plane covers the positioning magnetic ring 600, that is, from a top or bottom view on a side of the magnetic shielding structure 10, the magnetic shielding structure 10 covers and shields the positioning magnetic ring 600.

Referring to FIG. 7, in the illustrated embodiment, the edge of the magnetic shielding structure 10 extends beyond the edge of the positioning magnetic ring 600. The magnetic shielding structure 10 may extend beyond the edge of the positioning magnetic ring 600 in the radial direction of the positioning magnetic ring 600. The edge of the magnetic shielding structure 10 may alternatively extend beyond the edge of the positioning magnetic ring 600 in the axial direction of the positioning magnetic ring 600. Thus, the magnetic shielding structure 10 at least partially wraps the edge of the positioning magnetic ring 600 in the radial direction of the positioning magnetic ring 600. In an embodiment, the edge of the magnetic shielding structure 10 may be provided with a stepped structure to enhance the attenuation effect of the edge magnetic field. In other embodiments, the edge of the magnetic shielding structure 10 may be folded inward towards the positioning magnetic ring 600 to form a curled edge, thereby further reducing magnetic leakage.

Exemplarily, a specific size of the magnetic shielding structure 10 extending beyond the positioning magnetic ring 600 can be determined by technicians according to actual application requirements, such as 1 mm to 15 mm.

Exemplarily, the magnetic shielding structure 10 can be divided into asymmetric extension and symmetric extension in the process of extending beyond the edge of the positioning magnetic ring 600. When there is a need for directional shielding, the magnetic shielding structure 10 can extend in a specific direction and beyond the positioning magnetic ring 600, such as on a side adjacent to a sensitive element.

Exemplarily, an edge extension portion of the magnetic shielding structure 10 can alternatively be achieved by embedding or compounding other magnetic shielding materials, for example, by embedding high magnetic permeability alloy wires, such as Permalloy wires. In this way, a local magnetic field absorption network can be formed to further absorb the magnetic flux diffused at the edge and reduce edge leakage.

Exemplarily, by extending the edge of the magnetic shielding structure 10 beyond the edge of the positioning magnetic ring 600, the magnetic shielding structure 10 can further localize the magnetic field, suppress the diffusion of magnetic flux at the edge of the positioning magnetic ring 600, further enhance the magnetic attraction of the magnetic attraction positioning structure, and reduce the coupling interference of the external magnetic field on a system of the positioning magnetic ring 600 and electromagnetic coil 500.

FIG. 8 is a schematic diagram illustrating a distribution of magnetic induction lines of a magnetic attraction positioning structure in the related art. In conventional designs, the magnetic shielding structure 10 only covers the bottom of the transmitting coil. At this time, part of the magnetic induction lines generated by the positioning magnetic ring 600 and the magnetic ring of the corresponding device are absorbed to the surface of the positioning magnetic ring 600, and the other part diffuses outward.

FIG. 9 is a schematic diagram illustrating a distribution of magnetic induction lines of the magnetic attraction positioning structure according to an embodiment. The magnetic shielding structure 10 extends to a region of the positioning magnetic ring 600, so that the magnetic shielding structure 10 can cover the positioning magnetic ring 600 in the stacking direction. At this time, this extended design forces the magnetic field lines generated by the positioning magnetic ring 600 to be squeezed and concentrated on its surface, reducing the diffusion of the magnetic field to the surroundings, increasing the magnetic flux density on the surface of the positioning magnetic ring 600, that is, enhancing the surface magnetic strength of the positioning magnetic ring 600. On the other hand, the magnetic field of the positioning magnetic ring 600 would originally diverge into space, but the extended magnetic shielding structure 10 has high magnetic permeability, which can guide the magnetic field line to close along the surface of the magnetic shielding structure 10. This is equivalent to constructing a low magnetic resistance path around the positioning magnetic ring 600, so that more magnetic field lines are concentrated on the adsorption surface of the positioning magnetic ring 600 on an opposite side thereof, thereby enhancing the magnetic attraction of the magnetic attraction positioning structure. The magnetic shielding structure 10 covering the positioning magnetic ring 600 can further suppress magnetic field leakage, which helps to reduce interference with antennas of devices that need to be charged, such as mobile phones and tablets, and functions, such as near field communication (NFC) based on magnetic field communication. In the magnetic attraction positioning structure provided by the present disclosure, on the basis of meeting the size constraints of the wireless charging device, the magnetic force enhancement effect is achieved through structural characteristics by replacing the upgrading of the magnet material, realizing cost control of the magnetic attraction positioning structure, which helps to improve the alignment assistance effect of the position of the device during charging, and enhances the overall performance of magnetic positioning and the stability of the charging connection.

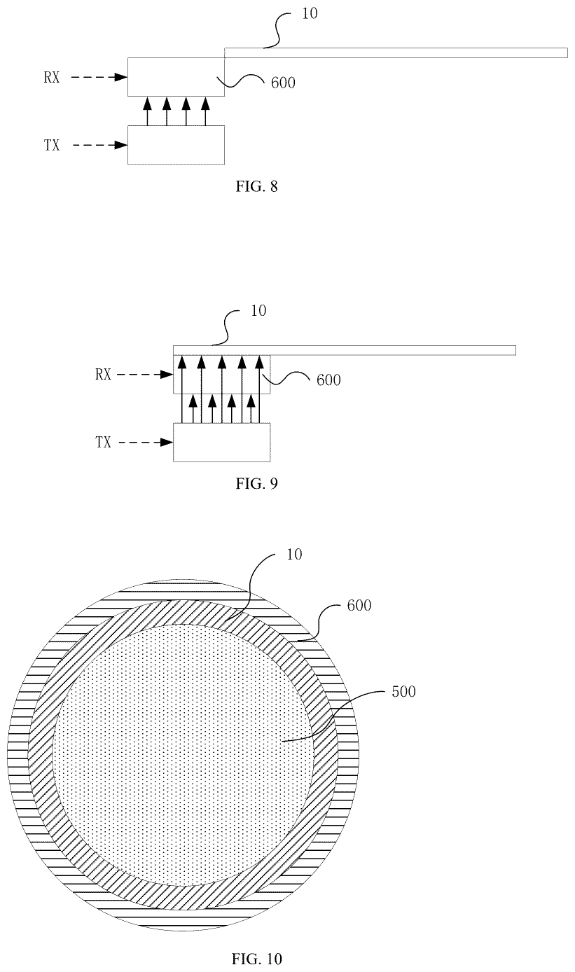

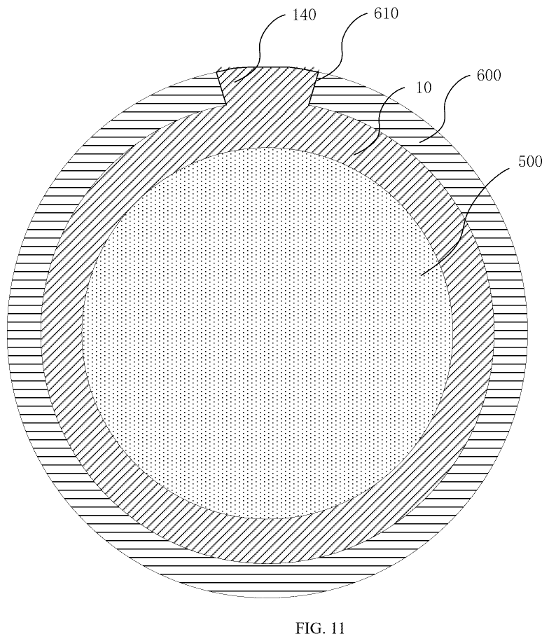

Referring to FIG. 10, in an embodiment, the positioning magnetic ring 600 can surround the magnetic shielding structure 10. When used in a wireless charging device, the positioning magnetic ring 600 also surrounds the electromagnetic coil 500.

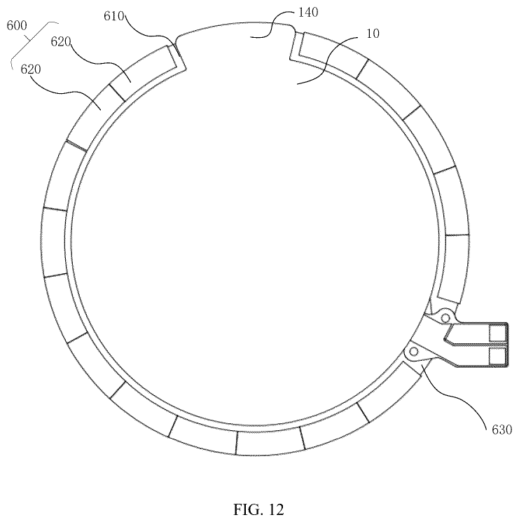

Referring to FIG. 11, the magnetic shielding structure 10 is surrounded by the positioning magnetic ring 600, and the positioning magnetic ring 600 is provided with a notch 610. Correspondingly, the magnetic shielding structure 10 has a protrusion 140 extending into the notch 610 and adapting to the notch 610. At this time, the protrusion 140 of the magnetic shielding structure 10 can fill a space formed by the notch 610 of the positioning magnetic ring 600, thereby assisting in adjusting the local magnetic field of the magnetic attraction positioning structure and enhancing the local magnetic flux. In addition, the fitting structure of the notch 610 and the protrusion 140 can enhance the mechanical cooperation relationship between the positioning magnetic ring 600 and the magnetic shielding structure 10 in the physical structure dimension, so that the relative position relationship between the positioning magnetic ring 600 and the magnetic shielding structure 10 is enhanced, and the possibility of misalignment due to rotation and sliding is reduced.

Specifically, in the preparation process of the positioning magnetic ring 600 and the magnetic shielding structure 10, the notch 610 can be made by stamping, milling, laser cutting, mold forming, etc. The protrusion 140 can be formed by stamping, deep drawing, directly formed during injection molding of the magnetic shielding structure 10, or by subsequent machining. The notch 610 may be a U-shaped groove, a square groove, a chamfered groove, a circular notch, a half-moon notch, a trapezoidal or polygonal incision, etc. The specific structure of the notch 610 is determined by technicians according to application requirements. The protrusion 140 can be a boss corresponding to the shape of the notch 610, such as a rectangular protrusion, a semicircular protrusion, a trapezoidal protrusion, etc.

Referring to FIG. 12, in an embodiment, the positioning magnetic ring 600 includes a plurality of magnets 620. Each magnet 620 may be sintered from a permanent magnet material such as neodymium iron boron (NdFeB) and meet preset size and geometry requirements. During the preparation process of the positioning magnetic ring 600, the plurality of magnets 620 can be distributed in a ring array along the magnetic ring and subjected to a pre-treatment of magnetization along the axial direction of the magnetic ring to form a unipolar or multi-polar distributed magnetic field.

The permanent magnetic material can refer to a type of material that can maintain strong magnetism for a long time after magnetization and is difficult to demagnetize. The core characteristics of the permanent magnetic material include high remanence (Br), high coercivity (Hc), and high magnetic energy product ((BH) max).

Exemplarily, the permanent magnetic material may include a metal permanent magnetic material, such as aluminum nickel cobalt (AlNiCo) and samarium cobalt (SmCo), a rare earth permanent magnetic material, such as neodymium iron boron (NdFeB) and samarium iron nitride (SmFeN), a ferrite permanent magnetic material, such as strontium or barium ferrite, and a new polymer permanent magnetic material, such as Mn—Al—C alloy and nano-composite permanent magnet.

When in use, the magnetic attraction positioning structure is provided in the wireless charging device, and the structure, shape, etc. of the magnetic attraction positioning structure would be limited by the structure of the wireless charging device, and it needs to work with related devices such as the electromagnetic coil 500, etc. The connectors or coils of related devices such as the electromagnetic coil 500 may need to be embedded in the magnetic shielding structure 10. In such scenarios, it is difficult for the magnetic shielding structure 10 to maintain a regular shape such as a round or rectangular shape. In view of the above problem, the positioning magnetic ring 600 is provided with a second avoidance opening 630. Thus, the positioning magnetic ring 600 can form a flexible and controllable space through the second avoidance opening 630, so that the positioning magnetic ring 600 can avoid other module structures or further reduce the thickness of the magnetic attraction positioning structure.

Exemplarily, the second avoidance opening 630 can be provided at the edge of the positioning magnetic ring 600, that is, the second avoidance opening 630 is formed at the edge of the positioning magnetic ring 600, thereby avoiding module structures such as the interface of the electromagnetic coil 500. The shape of the second avoidance opening 630 can be rectangular, circular, triangular, etc., and the specific shape thereof can be determined by the technician according to application requirements. In another embodiment, the second avoidance opening 630 can alternatively be provided in the middle of the positioning magnetic ring 600, that is, a through hole that meets application requirements is formed in the middle of the positioning magnetic ring 600, thereby realizing the requirement of forming a space in the middle of the magnetic attraction positioning structure. In the application of the two types of second avoidance opening 630 described above, since the second avoidance opening 630 is opened in the positioning magnetic ring 600, edge burrs may be formed in the magnetic attraction positioning structure, resulting in structural instability. Therefore, accordingly, rounding treatment can also be performed at the second avoidance opening 630 of the positioning magnetic ring 600. For example, the rounding treatment may refer to treating the corners of the second avoidance opening 630 to convert a sharp corner structure into a rounded corner, or may refer to adding a chamfer structure to an included angle of the section of the second avoidance opening 630 to convert the corner at the included angle from a sharp corner into a rounded corner. In this way, even if a plurality of second avoidance openings 630 of various shapes are added, the effect of reducing edge burrs in the positioning magnetic ring 600 can be maintained.

In this embodiment, by providing the second avoidance opening 630 in the ring array formed by the magnet 620 of the positioning magnetic ring 600, the application flexibility of the magnetic attraction positioning structure is improved.

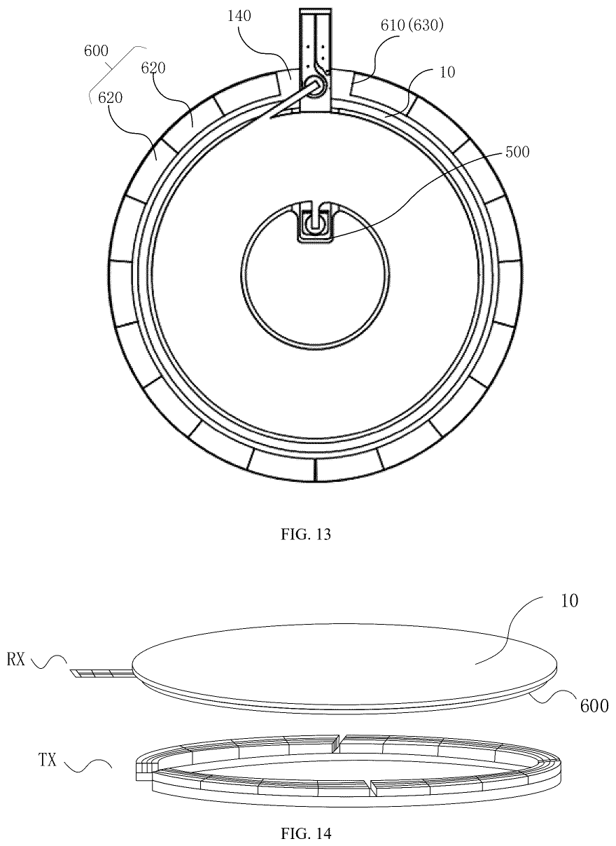

In the embodiment shown in FIG. 12, the second avoidance opening 630 and the notch 610 are located at different positions of the positioning magnetic ring 600. In another embodiment, as shown in FIG. 13, the second avoidance opening 630 and the notch 610 are located at the same position of the positioning magnetic ring 600.

Referring to FIGS. 10 to 13, a wireless charging device is further provided according to an embodiment of the present disclosure. The wireless charging device includes the magnetic attraction positioning structure as described in any one of the above embodiments and an electromagnetic coil 500. The magnetic shielding structure 10 of the magnetic attraction positioning structure covers the electromagnetic coil 500, and the electromagnetic coil 500 is surrounded by the positioning magnetic ring 600. In an embodiment, the intermediate layer 220 of the magnetic material layer 200 of the magnetic shielding structure 10 covers the central area of the electromagnetic coil 500.

The electromagnetic coil 500 is configured to convert electrical energy into a magnetic field and achieve wireless transmission of electrical energy through electromagnetic induction. Specifically, the electromagnetic coil 500 can be made through several structures, such as a winding topology structure, a coil forming structure, etc. Exemplarily, the winding topology structure may include multiple layers of gradual spiral windings. In this example, the electromagnetic coil 500 may be formed by stacking and winding multiple layers of copper foil wires having rectangular cross-sections, and adjacent layers of copper foil wires can be isolated by a high-temperature resistant polyimide insulating film. The turn spacing of each layer of copper foil wire increases gradually from the inside to the outside, for example, the turn spacing of the inner layer is 0.1 mm, and the turn spacing of the outer layer is 0.3 mm.

For example, a coil forming structure can form a wire pattern on a copper foil through a photolithography process. After multiple layers of wires are stacked alternately with insulating films, an integrated winding assembly is formed by hot pressing and curing. Subsequently, the winding assembly can be embedded in an inner cavity of the magnetic shielding structure 10 and encapsulated with epoxy resin, etc. In addition, the electromagnetic coil 500 can also be made by, for example, segmented windings, flexible coils, etc. which are similar to this embodiment and will not be described in detail here.

FIG. 14 is a schematic structural diagram of the wireless charging device. Specifically, the wireless charging device includes a transmitting end (TX end) and a receiving end (RX end). The TX end is a transmitting portion of the wireless charging system. The TX end is configured to generate an alternating electromagnetic field and transmit electrical energy through electromagnetic coupling or magnetic induction. The RX end is configured to receive electromagnetic energy from the TX end and convert it into electrical energy to supply loads (such as a smartphone, a battery, etc.). The magnetic attraction positioning structure in the embodiment of the present disclosure can be provided at the RX end. It should be understood that the magnetic shielding structure 10, the magnetic attraction positioning structure, and the wireless charging device described above can also adopt other forms, and are not limited to the forms mentioned in the above embodiments, as long as they can achieve the purpose of improving the function of the magnetic shielding structure 10.

In the description of this specification, the description with reference to the terms “some embodiments”, “other embodiments”, etc. means that the specific features, structures, materials or characteristics described in conjunction with the embodiment are included in at least one embodiment of the present disclosure. In this specification, the illustrative descriptions of the above terms do not necessarily refer to the same embodiment.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure. Therefore, the protection scope of the present disclosure shall be subject to the protection scope of the appended claims.

What is claimed is:

1. A magnetic shielding structure, comprising:
a magnetic material layer; and
a first edge-wrapping structure layer and a second edge-wrapping structure layer that are provided on both sides of the magnetic material layer, respectively;
wherein the magnetic material layer comprises a first covering layer, an intermediate layer, and a second covering layer that are sequentially stacked, an area of the intermediate layer is less than an area of each of the first covering layer and the second covering layer, and the first covering layer and the second covering layer wrap the intermediate layer from both sides of the intermediate layer, respectively.

2. The magnetic shielding structure according to claim 1, wherein at least one of the first covering layer, the intermediate layer, and the second covering layer comprises a plurality of magnetic material sheets.

3. The magnetic shielding structure according to claim 2, wherein the magnetic material sheet is made of a magnetic material, and the magnetic material is at least one selected from the group consisting of a ferrite material, an amorphous alloy, a nanocrystalline alloy, a soft magnetic composite material, and a flexible magnetic film.

4. The magnetic shielding structure according to claim 1, wherein the intermediate layer is provided with a first avoidance opening.

5. The magnetic shielding structure according to claim 1, further comprising:
a shielding layer provided on a side of the first edge-wrapping structure layer or the second edge-wrapping structure layer away from the magnetic material layer.

6. The magnetic shielding structure according to claim 5, wherein the shielding layer is a sheet structure made of a metal material.

7. The magnetic shielding structure according to claim 1, further comprising:
adhesive layers provided between the first edge-wrapping structure layer, the magnetic material layer, and the second edge-wrapping structure layer.

8. The magnetic shielding structure according to claim 1, further comprising:
adhesive layers provided between the first covering layer, the intermediate layer, and the second covering layer.

9. A magnetic attraction positioning structure, comprising:
the magnetic shielding structure according to claim 1; and
a positioning magnetic ring stacked on the magnetic shielding structure in a stacking direction, wherein the magnetic shielding structure covers the positioning magnetic ring in the stacking direction.

10. The magnetic attraction positioning structure according to claim 9, wherein an edge of the magnetic shielding structure is aligned with an edge of the positioning magnetic ring.

11. The magnetic attraction positioning structure according to claim 9, wherein an edge of the magnetic shielding structure extends beyond an edge of the positioning magnetic ring in a radial direction of the positioning magnetic ring.

12. The magnetic attraction positioning structure according to claim 11, wherein an edge of the magnetic shielding structure extends beyond an edge of the positioning magnetic ring in an axial direction of the positioning magnetic ring.

13. The magnetic attraction positioning structure according to claim 12, wherein the edge of the magnetic shielding structure is provided with a stepped structure.

14. The magnetic attraction positioning structure according to claim 12, wherein the edge of the magnetic shielding structure is folded inward towards the positioning magnetic ring to form a curled edge.

15. A magnetic attraction positioning structure, comprising:
the magnetic shielding structure according to claim 1; and
a positioning magnetic ring surrounding the magnetic shielding structure.

16. The magnetic attraction positioning structure according to claim 15, wherein the positioning magnetic ring has a notch, and the magnetic shielding structure has a protrusion extending into the notch.

17. The magnetic attraction positioning structure according to claim 15, wherein the positioning magnetic ring comprises a plurality of magnets distributed in a ring array.

18. The magnetic attraction positioning structure according to claim 15, wherein the positioning magnetic ring is provided with a second avoidance opening.

19. A wireless charging device, comprising:
the magnetic attraction positioning structure according to claim 9; and
an electromagnetic coil, wherein the magnetic shielding structure of the magnetic attraction positioning structure covers the electromagnetic coil, and the electromagnetic coil is surrounded by the positioning magnetic ring of the magnetic attraction positioning structure.

20. A wireless charging device, comprising:
the magnetic attraction positioning structure according to claim 15; and
an electromagnetic coil, wherein the magnetic shielding structure of the magnetic attraction positioning structure covers the electromagnetic coil, and the electromagnetic coil is surrounded by the positioning magnetic ring of the magnetic attraction positioning structure.
